(19) United States
(12) Patent Application Publication
(10) Pub. No.: US 2009/0114991 A1
(43) Pub. Date: May 7, 2009

(54) SEMICONDUCTOR DEVICES HAVING A CONTACT STRUCTURE AND METHODS OF FABRICATING THE SAME

(75) Inventors: Dae-Ik Kim, Gyeonggi-do (KR); Won-Woo Lee, Gyeonggi-do (KR); Yong-Il Kim, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/199,458

(22) Filed: Aug. 27, 2008

(30) Foreign Application Priority Data
Aug. 28, 2007 (KR) 10-2007-0086560

(51) Int. Cl. H01L 29/78; H01L 21/336

(52) U.S. Cl. 257/365; 438/268; 438/270; 257/773; 257/E21.409; 257/E29.255

(57) ABSTRACT

A semiconductor device includes an isolation region formed in a semiconductor substrate to define an active region. First and second impurity regions spaced apart from each other are formed in the active region. A gate trench region crosses the active region between the first and second impurity regions and extends to the isolation region. A first contact structure having a sidewall in vertical alignment with a sidewall of the gate trench region adjacent to the first impurity region is provided on the first impurity region. A second contact structure having a sidewall in vertical alignment with a sidewall of the gate trench region adjacent to the second impurity region is provided on the second impurity region. A gate electrode is provided in the gate trench region. A gate dielectric layer is interposed between the gate trench region and the gate electrode.

### CROSS-REFERENCE TO RELATED APPLICATION

This application claims the benefit of Korean Patent Application No. 10-2007-0086560, filed on Aug. 28, 2007, the disclosure of which is hereby incorporated herein by reference in its entirety.

### FIELD OF THE INVENTION

The present invention relates to semiconductor devices and methods of fabricating the same, and, more particularly, to semiconductor devices having a contact structure and methods of fabricating the same.

### BACKGROUND OF THE INVENTION

In recent times, as a memory device such as a DRAM is highly integrated, an area of a discrete device, such as a MOS transistor, gradually decreases. Particularly, when a short channel effect occurs in an access MOS transistor used in a memory cell of a DRAM device, leakage current of a DRAM cell generally increases, such that a refresh characteristic of the DRAM device is degraded. Accordingly, a recess channel MOS transistor may be used as a MOS transistor suitable for inhibition of the short channel effect while the DRAM device is more integrated. Further, as a design rule and a chip size of the memory cell of a semiconductor device, such as a DRAM decrease, it may be more difficult to overcome the limitation in photolithography and ensure a sufficient process margin. Particularly, according to an increase in the degree of integration of a semiconductor device, contact holes may become smaller and have a smaller gap therebetween, such that it may be even more difficult to form fine contact holes by a photolithography process.

### SUMMARY

Some embodiments of the present invention may provide semiconductor devices having a contact structure with an increased contact area.

Further embodiments of the present invention may provide methods of fabricating a semiconductor device having a contact structure with an increased contact area.

According to some embodiments of the present invention, a semiconductor device includes first and second regions formed in a semiconductor substrate and spaced apart from each other. A first contact structure having a sidewall in vertical alignment with a sidewall of the first region facing the second region is provided on the first region. A second contact structure having a sidewall in vertical alignment with a sidewall of the second region facing the first region is provided on the second region.

In other embodiments, the first contact structure may be electrically connected to the first region and may cover a top surface of the first region, and the second contact structure may be electrically connected to the second region and may cover a top surface of the second region.

In still other embodiments, the first contact structure may include a first contact pattern electrically connected to the first region and a first conductive contact spacer provided on a sidewall other than a sidewall facing the second contact structure among the sidewalls of an upper region of the first contact pattern, and the second contact structure may include a second contact pattern electrically connected to the second region and a second conductive contact spacer provided on a sidewall other than a sidewall facing the first contact structure among the sidewalls of an upper region of the second contact pattern.

In further embodiments, a semiconductor device having a contact structure with an increased contact area with an impurity region is provided. The semiconductor device includes an isolation region formed in a semiconductor substrate to define an active region. First and second impurity regions spaced apart from each other are formed in the active region. A gate trench region crossing the active region between the first and second impurity regions and extending to the isolation region is provided. A first contact structure having a sidewall in vertical alignment with a sidewall of the gate trench region adjacent to the first impurity region is provided on the first impurity region. A second contact structure having a sidewall in vertical alignment with a sidewall of the gate trench region adjacent to the second impurity region is provided on the second impurity region. A gate electrode is provided in the gate trench region. A gate dielectric layer is interposed between the gate trench region and the gate electrode.

In still further embodiments, the first contact structure may be electrically connected to the first impurity region and may cover a top surface of the first impurity region, and the second contact structure may be electrically connected to the second impurity region and may cover a top surface of the second impurity region.

In still further embodiments, the first contact structure may include a first contact pattern electrically connected to the first impurity region, and a first conductive contact spacer provided on a sidewall other than a sidewall facing the second contact structure among the sidewalls of an upper region of the first contact pattern, and the second contact structure may include a second contact pattern electrically connected to the second impurity region, and a second conductive contact spacer provided on a sidewall other than a sidewall facing the first contact structure among the sidewalls of an upper region of the second contact pattern.

In still further embodiments, the gate electrode may be formed of a metallic material.

In still further embodiments, the semiconductor device may further include an other active region defined by the isolation region and spaced apart from the active region and a transistor provided on the other active region.

In still further embodiments, the other active region may have a top surface disposed at a different level than a top surface of the active region.

In other embodiments, a method of fabricating a semiconductor device having a contact structure is provided. The method includes forming an insulating layer having an opening on a semiconductor substrate having a contact forming region to expose the contact forming region through the opening. Contact structures spaced apart from each other are formed on the contact forming region exposed through the opening. The contact structures may be formed of a conductive material. The contact forming region between the contact structures are etched so as to form a trench region for dividing the contact forming region.

In still other embodiments, forming the contact structures may include forming a contact conductive layer filling the opening in the insulating layer, and patterning the contact conductive layer.

In still other embodiments, the contact structures may include contact patterns electrically connected with the contact forming region, and contact spacers formed on sidewalls other than sidewalls facing each other among the sidewalls of upper regions of the contact patterns.

In still other embodiments, forming the contact structures may include forming a contact conductive layer filling the opening in the insulating layer, partially etching the insulating layer using the contact conductive layer as an etch mask to expose a sidewall of an upper region of the contact conductive layer, forming a conductive spacer on the exposed sidewall of the upper region of the contact conductive layer, and patterning the contact conductive layer and the conductive spacer to form the contact patterns and the contact spacers.

In further embodiments, a method of fabricating a semiconductor device having a contact structure with an increased contact area with an impurity region is provided. The method includes forming an isolation region in a semiconductor substrate to define an active region. An interlayer insulating layer having an opening is formed on the semiconductor substrate having the isolation region to expose the active region through the opening. A contact conductive layer filling the opening is formed. A mask pattern having an opening is formed to cross the contact conductive layer and extend onto the interlayer insulating layer. The contact conductive layer, the interlayer insulating layer, the active region and the isolation region are etched using the mask pattern as an etch mask, and a gate trench region crossing the active region and extending to the isolation region, and first and second contact structures spaced apart from each other on the active region are formed. A gate dielectric layer is formed on the gate trench region. A gate electrode partially filling the gate trench region is formed on the gate dielectric layer.

In still further embodiments, before forming the contact conductive layer, a preliminary impurity region may be formed in the active region and divided by the gate trench region to define source and drain regions.

In still further embodiments, the active region exposed through the opening may be isotropically etched using the interlayer insulating layer as an etch mask.

In still further embodiments, the isolation region may define an other active region spaced apart from the active region in the semiconductor substrate, and before forming the interlayer insulating layer, a transistor may be formed on the other active region.

In other embodiments, a method of fabricating a semiconductor device having a contact structure with an increased top surface area is provided. The method includes forming an isolation region to define an active region in a semiconductor substrate. An interlayer insulating layer having an opening is formed on the semiconductor substrate having the isolation region to expose the active region through the opening. A contact conductive layer filling the opening is formed. The interlayer insulating layer is etched to expose a sidewall of an upper region of the contact conductive layer. A conductive spacer is formed on the exposed sidewall of the contact conductive layer. A mask pattern having an opening is formed to cross the contact conductive layer and extend onto the interlayer insulating layer. The contact conductive layer, the conductive spacer, the interlayer insulating layer, the active region and the isolation region are etched using the mask pattern as an etch mask, and a gate trench region crossing the active region and extending to the isolation region is formed. A gate dielectric layer is formed on the gate trench region. A gate electrode partially filling the gate trench region is formed on the gate dielectric layer.

In still other embodiments, before forming the contact conductive layer, a preliminary impurity region may be formed in the active region and divided by the gate trench region to define source and drain regions.

In still other embodiments, the active region exposed through the opening may be isotropically etched using the interlayer insulating layer as an etch mask.

In still other embodiments, the isolation region may define an other active region spaced apart from the active region in the semiconductor substrate, and before forming the interlayer insulating layer, a transistor may be formed on the other active region.

### BRIEF DESCRIPTION OF THE DRAWINGS

The foregoing and other objects, features and advantages of the invention will become more apparent from the following more particular description of example embodiments of the invention and the accompanying drawings. The drawings are not necessarily to scale, emphasis instead being placed upon illustrating the principles of the invention.

FIG. 1 is a plan view of a semiconductor device according to example embodiments of the present invention.

FIGS. 2A to 2F are cross-sectional views of a semiconductor device according to an example embodiment of the present invention.

FIGS. 3A to 3E are cross-sectional views of a semiconductor device according to another example embodiment of the present invention.

### DETAILED DESCRIPTION OF EMBODIMENTS OF THE INVENTION

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout the description of the figures.

It will be understood that when an element is referred to as being “on” another element, it can be directly on the other element or intervening elements may be present. In contrast, when an element is referred to as being “directly on” another element, there are no intervening elements present. It will be understood that when an element is referred to as being “connected” or “coupled” to another element, it can be directly connected or coupled to the other element or intervening elements may be present. In contrast, when an element is referred to as being “directly connected or coupled” to another element, there are no intervening elements present. Furthermore, “connected” or “coupled” as used herein may include wirelessly connected or coupled. As used herein, the term “and/or” includes any and all combinations of one or more of the associated listed items.

It will be understood that, although the terms first, second, etc. may be used herein to describe various elements, these elements should not be limited by these terms. These terms are only used to distinguish one element from another. For example, a first layer could be termed a second layer, and, similarly, a second layer could be termed a first layer without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to other elements as illustrated in the Figures. It will be understood that relative terms are intended to encompass different orientations of the device in addition to the orientation depicted in the Figures. For example, if the device in one of the figures were turned over, elements described as being on the “lower” side of other elements would then be oriented on “upper” sides of the other elements. The exemplary term “lower”, can therefore, encompass both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

In the description, a term “substrate” used herein may include a structure based on a semiconductor, having a semiconductor surface exposed. It should be understood that such a structure may contain silicon, silicon on insulator, silicon on sapphire, doped or undoped silicon, epitaxial layer supported by a semiconductor substrate, or another structure of a semiconductor. And, the semiconductor may be silicon-germanium, germanium, or germanium arsenide, not limited to silicon. In addition, the substrate described hereinafter may be one in which regions, conductive layers, insulation layers, their patterns, and/or junctions are formed.

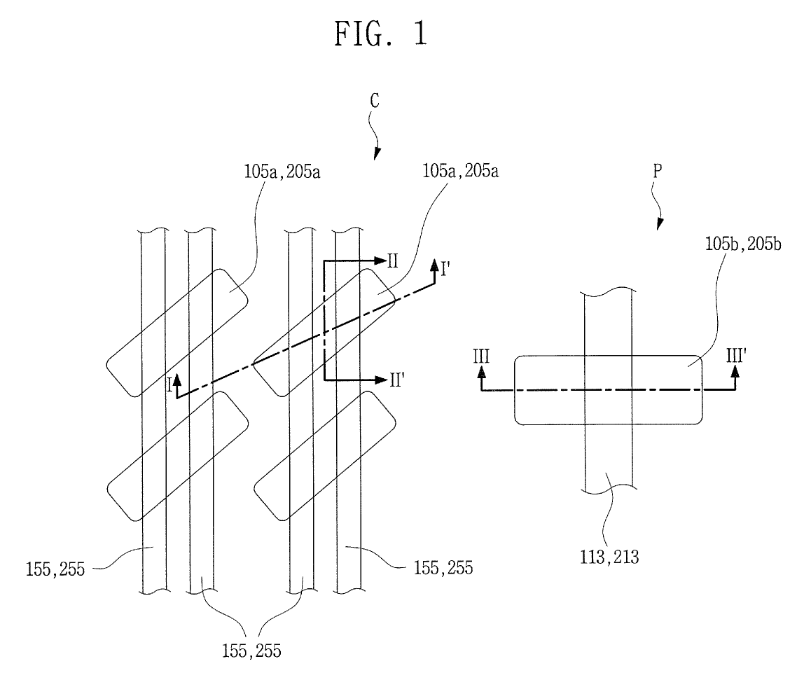

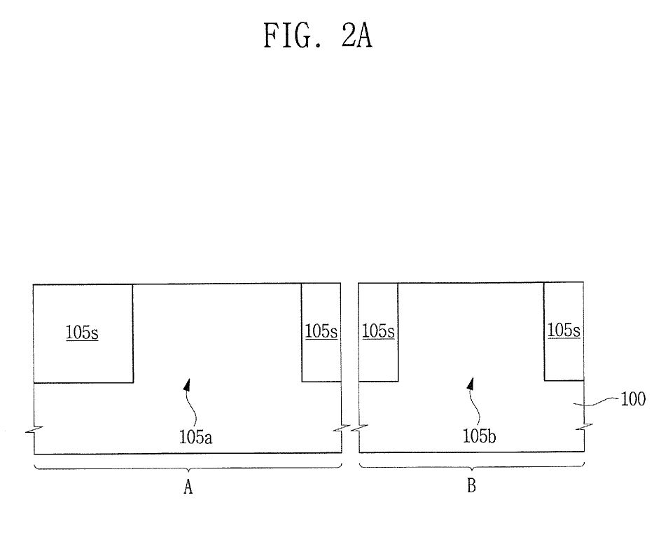

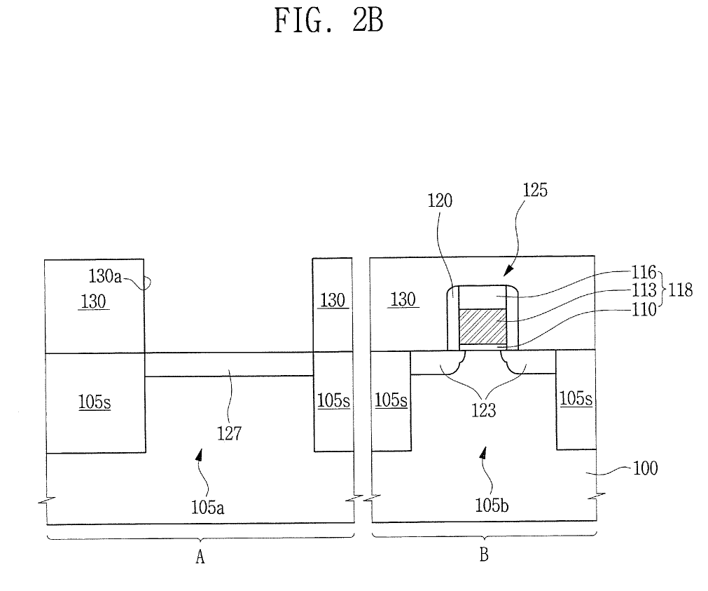

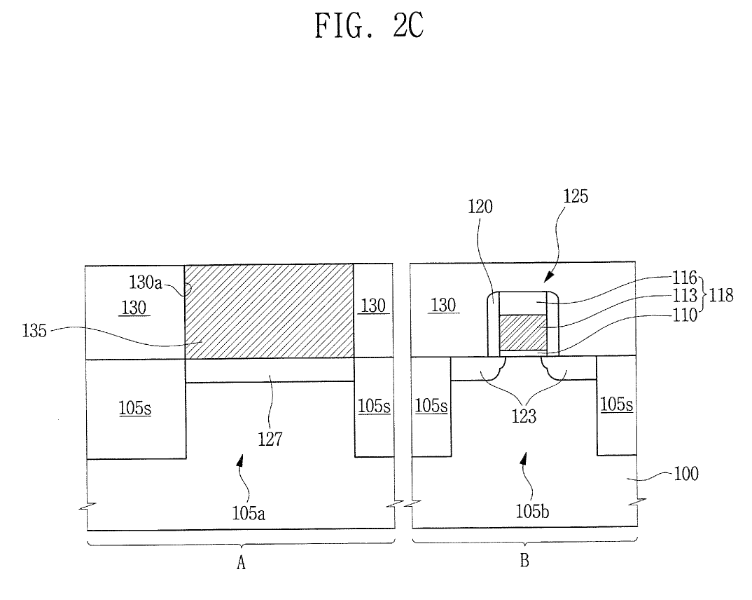

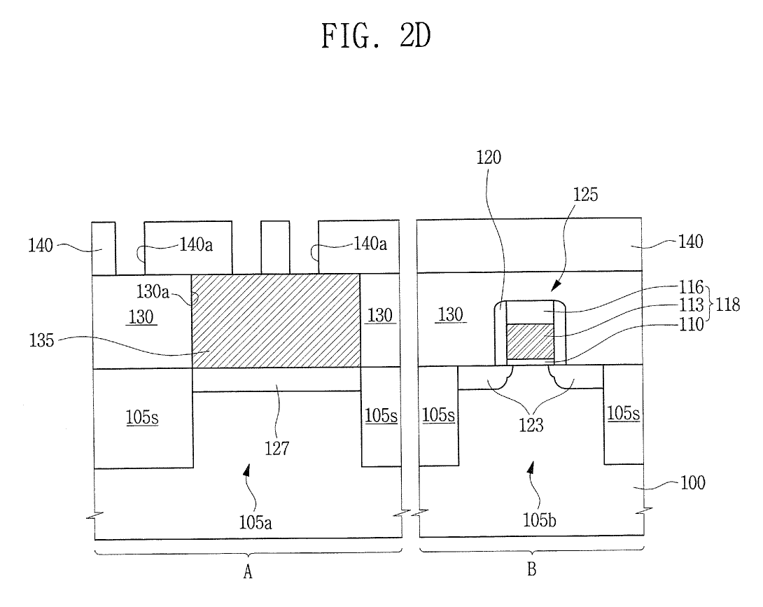

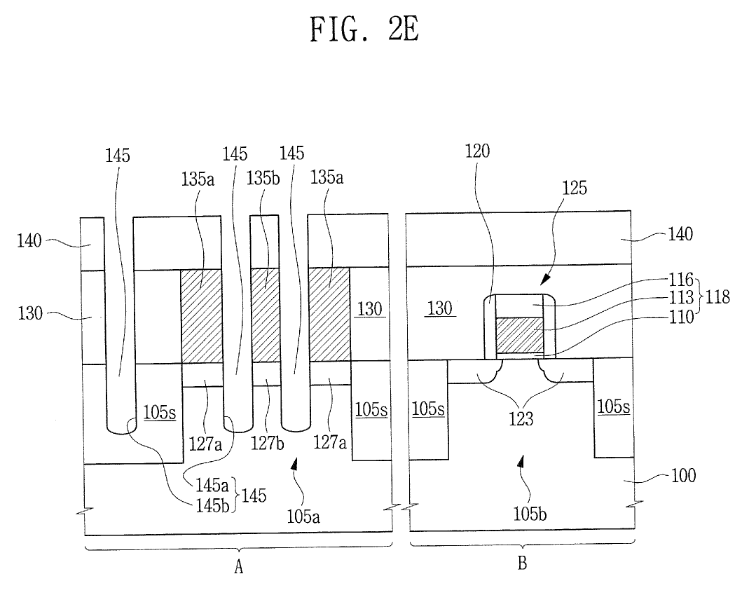

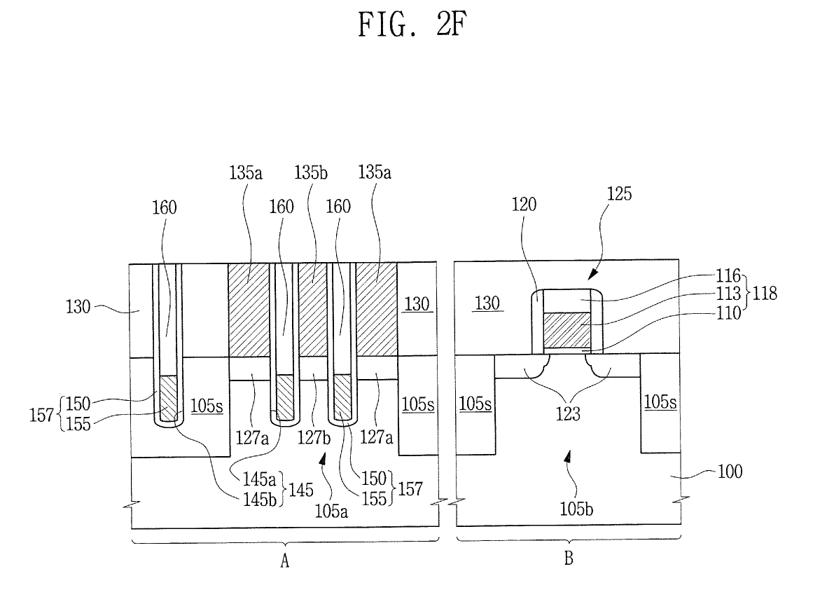

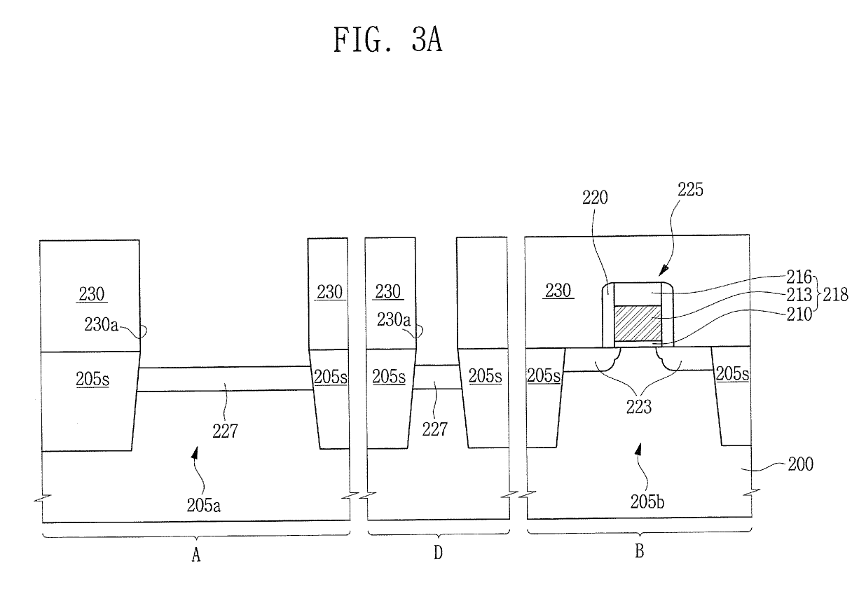

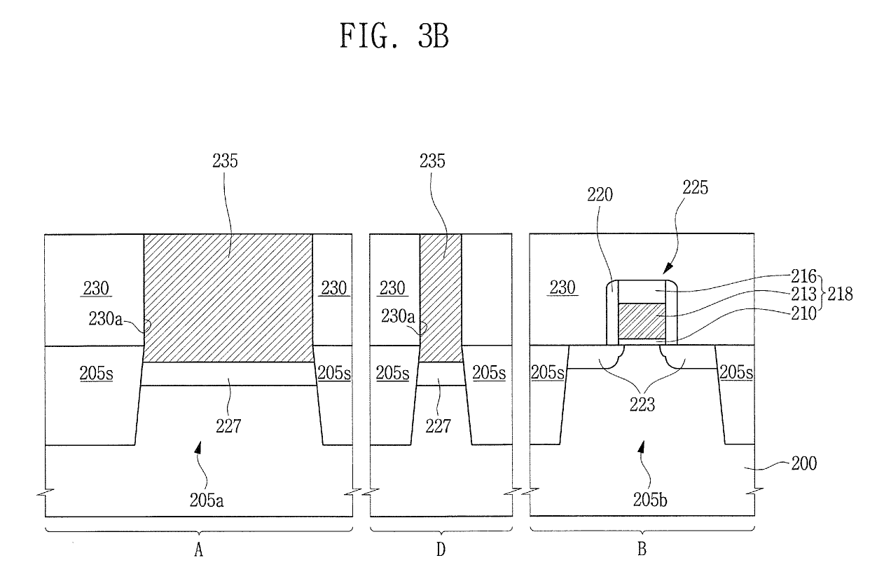

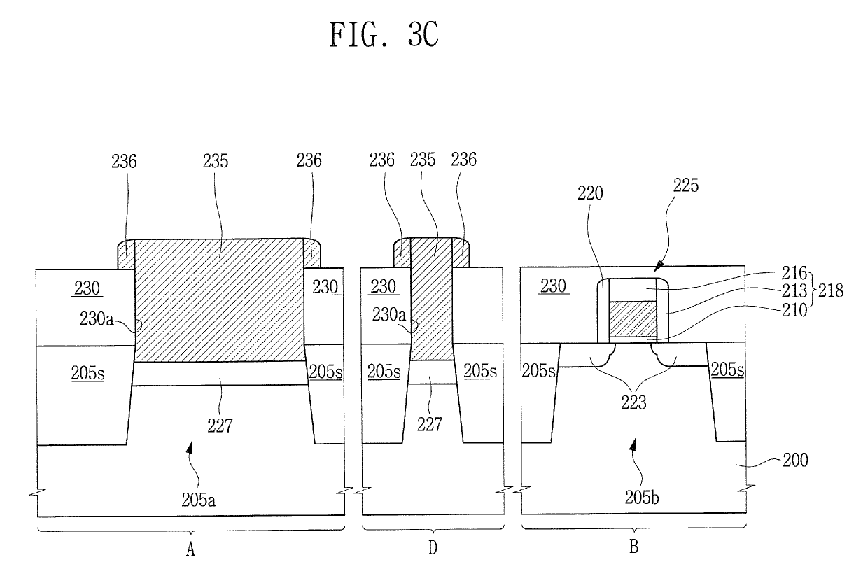

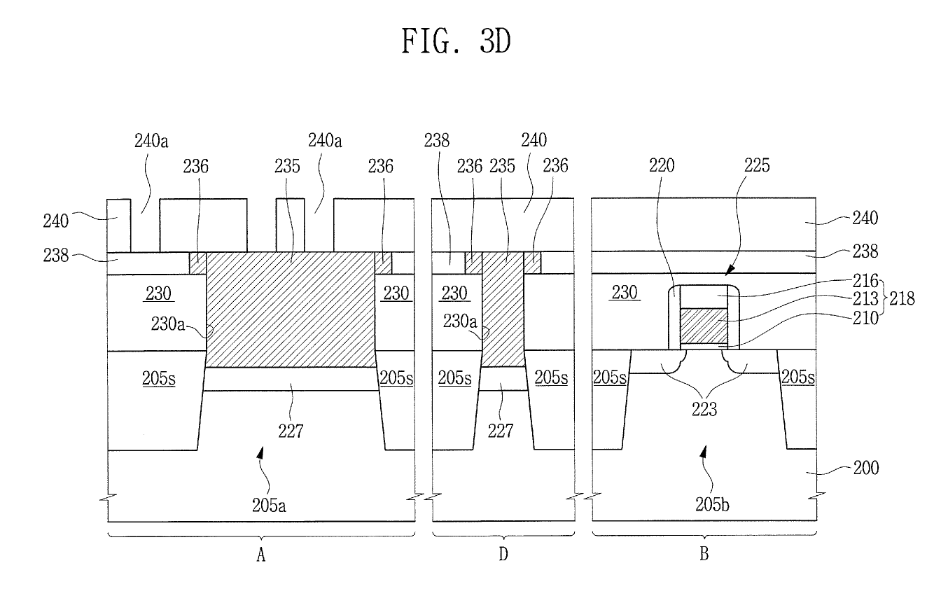

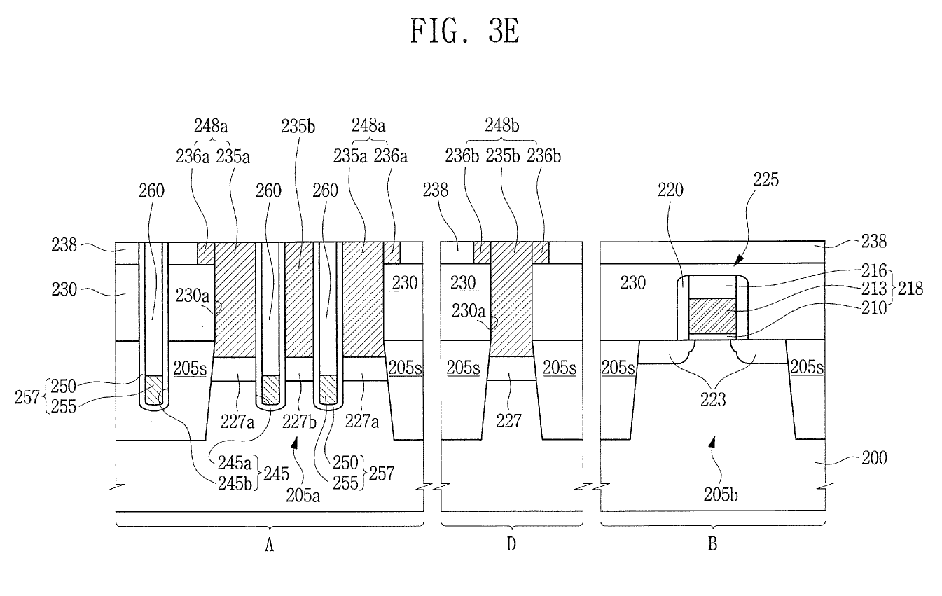

FIG. 1 is a plan view of a semiconductor device according to example embodiments of the present invention, FIGS. 2A to 2F are cross-sectional views of a semiconductor device according to an example embodiment of the present invention, and FIGS. 3A to 3E are cross-sectional views of a semiconductor device according to another example embodiment of the present invention.

In FIG. 1, “C” is a first circuit region of a semiconductor device, and “P” is a second circuit region of the semiconductor device. In FIGS. 2A to 2F and 3A to 3E, “A” is a region taken along line I-I′ of FIG. 1, and “B” is a region taken along line III-III′ of FIG. 1. Further, in FIGS. 3A to 3E, “D” is a region taken along line II-II′ of FIG. 1.

First, a structure of a semiconductor device according to an example embodiment of the present invention will be described with reference to FIGS. 1 and 2F.

Referring to FIGS. 1 and 2F, a semiconductor substrate 100 having a first circuit region C and a second circuit region P may be provided. The semiconductor substrate 100 may be a silicon substrate. The first circuit region C may be a circuit region having a fine gate line width, and the second circuit region P may be a circuit region having a larger gate line width than that of the first circuit region C. For example, when the present invention is embodied in a memory device, the first circuit region C may be a cell array region, and the second circuit region P may be a peripheral circuit region.

An isolation region 105s may be provided in the semiconductor substrate 100 to define active regions 105a and 105b. The isolation region 105s defines a first active region 105a in the first circuit region C and a second active region 105b in the second circuit region P. When the present invention is embodied in a memory device, the first active region 105a may be defined as a cell active region 105a of the cell array region and the second active region 105b may be defined as a peripheral active region 105b of the peripheral circuit region.

The isolation region 105s may be a trench isolation layer including a silicon oxide layer. An upper region and a lower region of the isolation region 105s may have substantially the same width, but embodiments of the present invention are not limited thereto. For example, the isolation region 105s may be formed in various shapes, such as an inverted-trapezoidal shape, in which the upper region has a larger width than the lower region, or a trapezoidal shape, in which the upper region has a smaller width than the lower region.

In the present embodiment, the cell active region 105a and the peripheral active region 105b may have top surfaces disposed at substantially the same level, but embodiments of the present invention are not limited thereto. For example, as in another example embodiment to be described later, the cell active region 105a may have the top surface disposed at a lower level than that of the peripheral active region 105b.

A first impurity region 127a and a second impurity region 127b may be provided in the cell active region 105a and spaced apart from each other. A gate trench region 145 may be provided, which crosses the cell active region 105a between the first and second impurity regions 127a and 127b and extends to the isolation region 105s. In other words, the gate trench region 145 may include an active trench region 145a crossing the cell active region 105a between the first and second impurity regions 127a and 127b, and a field trench region 145b extending to the isolation region 105s from the active trench region 145a.

A first contact structure 135a may be provided on and electrically connected with the first impurity region 127a. The first contact structure 135a may have a sidewall in vertical alignment with a sidewall of the gate trench region 145 adjacent to the first impurity region 127a. That is, the first contact structure 135a may have a sidewall in vertical alignment with a sidewall of the first impurity region 127a facing the second impurity region 127b. A second contact structure 135b may be provided on and electrically connected with the second impurity region 127b. The second contact structure 135b may have a sidewall in vertical alignment with a sidewall of the gate trench region 145 adjacent to the second impurity region 127b. That is, the second contact structure 135b may have a sidewall in vertical alignment with a sidewall of the second impurity region 127b facing the first impurity region 127a. The first and second contact structures 135a and 135b may be formed of the same material. For example, the first and second contact structures 135a and 135b may be formed of a polysilicon layer.

The first contact structure 135a may completely cover a top surface of the first impurity region 127a. Thus, a contact resistance characteristic between the first contact structure 135a and the first impurity region 127a may be improved. Further, the second contact structure 135b may completely cover a top surface of the second impurity region 127b. Thus, a contact resistance characteristic between the second contact structure 135b and the second impurity region 127b may be improved.

A gate electrode 155 may be provided in the gate trench region 145. The gate electrode 155 may comprise a metallic material or a polysilicon material. For example, the metallic material may comprise a metal nitride such as a titanium nitride (TiN). The gate electrode 155 may be disposed at a lower level than the top surface of the cell active region 105a and the top surface of the isolation region 105s, but embodiments of the present invention are not limited thereto. For example, the gate electrode 155 may have a top surface disposed at substantially the same level as the top surface of the cell active region 105a, or a top surface disposed at a higher level than the top surface of the cell active region 105a. A gate dielectric layer 150 may be provided, which is interposed between the gate electrode 155 and the gate trench region 145. The gate dielectric layer 150 may be formed of a thermal oxide layer or a high-k dielectric layer. The gate dielectric layer 150 and the gate electrode 155 may constitute a gate pattern 157.

An insulating pattern 160 may be provided on the gate electrode 155. The insulating pattern 160 may be self-aligned with the gate electrode 155, and interposed between the first contact structure 135a and the second contact structure 135b. Further, the insulating pattern 160 may have a top surface disposed at substantially the same level as top surfaces of the first and second contact structures 135a and 135b.

A peripheral transistor 125 may be provided on the peripheral active region 105b in the semiconductor substrate 100. The peripheral transistor 125 may be a planar-type transistor. The peripheral transistor 125 may include a peripheral gate pattern 118 on the peripheral active region 105b and peripheral source and drain regions 123 provided in the peripheral active region 105b at both sides of the peripheral gate pattern 118. The peripheral gate pattern 118 may include a peripheral gate dielectric layer 110, a peripheral gate electrode 113 and a capping mask 116, which are stacked sequentially. The peripheral gate electrode 113 may have a larger width than the gate electrode 155. In some embodiments, the capping mask 116 may be omitted. A gate spacer 120 may be provided on a sidewall of the peripheral gate pattern 118.

Next, a structure of a semiconductor device according to another example embodiment of the present invention will be described with reference to FIGS. 1 and 3E.

Referring to FIGS. 1 and 3E, as described in FIG. 2F, an isolation region 205s may be provided in a semiconductor substrate 200 having a first circuit region C and a second circuit region P to define active regions 205a and 205b. That is, the isolation region 205s may define a first active region, i.e., a cell active region 205a, in the first circuit region C, and a second active region, i.e., a peripheral active region 205b, in the second circuit region P. The isolation region 205s may be a trench isolation layer including a silicon oxide layer. The isolation region 205s may be formed in an inverted-trapezoidal shape in which an upper region has a larger width than a lower region, but the present invention is not limited thereto. For example, the isolation region 205s may be formed in various shapes, such as a shape in which the upper region has substantially the same width than the lower region, or a trapezoidal shape in which the upper region has a smaller width than the lower region.

In the present embodiment, the cell active region 205a may have a top surface disposed at a lower level than a top surface of the peripheral active region 205b, but the present invention is not limited thereto. For example, the cell active region 205a and the peripheral active region 205b may have top surfaces disposed at substantially the same level.

A first impurity region 227a and a second impurity region 227b may be provided in the cell active region 205a and spaced apart from each other. A gate trench region 245 may be provided, which crosses the cell active region 205a between the first and second impurity regions 227a and 227b, and extends to the isolation region 205s. In other words, the gate trench region 245 may include an active trench region 245a crossing the cell active region 205a between the first and second impurity regions 227a and 227b, and a field trench region 245b extending to the isolation region 205s from the active trench region 245a.

A first contact structure 248a may be provided on and electrically connected with the first impurity region 227a. Further, a second contact structure 248b spaced apart from the first contact structure 248b and electrically connected with the second impurity region 227b may be provided on the second impurity region 227b. The first contact structure 248a may have a sidewall in vertical alignment with a sidewall of the gate trench region 245 adjacent to the first impurity region 227a. That is, the first contact structure 248a may have a sidewall in vertical alignment with a sidewall of the first impurity region 227a facing the second impurity region 227b. The first contact structure 248a may include a first contact pattern 235a electrically connected with the first impurity region 227a, and a first conductive contact spacer 236a provided on a sidewall other than a sidewall facing the second contact structure 248b among the sidewalls of the upper region of the first contact pattern 235a. The second contact structure 248b may have a sidewall in vertical alignment with a sidewall of the gate trench region 245 adjacent to the second impurity region 227b. The second contact structure 248b may include a second contact pattern 235b electrically connected with the second impurity region 227b and a second conductive contact spacer 236b provided on a sidewall other than a sidewall facing the first contact structure 248a among the sidewalls of the upper region of the second contact pattern 235b. The first and second contact structures 248a and 248b may be formed of the same material. For example, the first and second contact structures 248 and 248b may be formed of a polysilicon layer.

The first contact pattern 235a of the first contact structure 248a may completely cover a top surface of the first impurity region 227a. Thus, a contact resistance characteristic between the first contact structure 248a and the first impurity region 227a may be improved. Further, the second contact pattern 235b of the second contact structure 248b may completely cover a top surface of the second impurity region 227b. Thus, a contact resistance characteristic between the second contact structure 248b and the second impurity region 227b may be improved. Further, the first and second contact structures 248a and 248b may be provided to have large top surface areas due to the first and second contact spacers 236a and 236b, respectively.

As described in FIG. 2F, a gate electrode 255 may be provided in the gate trench region 245. Further, a gate dielectric layer 250 may be provided, which is interposed between the gate electrode 255 and the gate trench region 245. The gate dielectric layer 250 may be formed of a silicon oxide layer or a high-k dielectric layer. The gate insulating layer 250 and the gate electrode 255 may constitute a gate pattern 257.

An insulating pattern 260 may be provided on the gate electrode 255. The insulating pattern 260 may be self-aligned with the gate electrode 255, and interposed between the first contact structure 248a and the second contact structure 248b. In addition, the insulating pattern 260 may have a top surface disposed at substantially the same level as the top surfaces of the first and second contact structures 248a and 248b. As described in FIG. 2F, a peripheral transistor 225 may be provided on the peripheral active region 205b in the semiconductor substrate 200.

A method of fabricating a semiconductor device according to example embodiments of the present invention will now be described.

First, a method of fabricating a semiconductor device according to an example embodiment of the present invention will be described with reference to FIGS. 1, and 2A to 2F.

Referring to FIGS. 1 and 2A, a semiconductor substrate 100 having a first circuit region C and a second circuit region P is prepared. The semiconductor substrate 100 may be a silicon substrate. The first circuit region C may be a circuit region having a fine gate line width and the second circuit region P may be a circuit region having a larger gate line width than that of the first circuit region C. For example, when the present invention is embodied in a memory device, the first circuit region C may be a cell array region and the second circuit region P may be a peripheral circuit region.

An isolation region 105s may be formed in the semiconductor substrate 100 to define active regions 105a and 105b. The isolation region 105s may be formed of a silicon oxide layer. To be more specific, the isolation region 105s may define a first active region, i.e., a cell active region 105a, in the first circuit region C, and a second active region, i.e., a peripheral active region 105b, in the second circuit region P. The isolation region 105s may be formed by a shallow trench isolation process. The isolation process 105s may be formed in a shape in which an upper region and a lower region have substantially the same width, but embodiments of the present invention are not limited thereto. For example, the isolation region 105s may be formed in various shapes, such as an inverted-trapezoidal shape in which an upper region has a larger width than a lower region or a trapezoidal shape in which the upper region has a smaller width than the lower region.

Referring to FIGS. 1 and 2B, a peripheral transistor 125 may be formed on the peripheral active region 105b in the semiconductor substrate 100. To be more specific, forming the peripheral transistor 125 may include forming a peripheral gate pattern 118 on the peripheral active region 105b, forming a gate spacer 120 on a sidewall of the peripheral gate pattern 118, and forming peripheral impurity regions, i.e., source and drain regions 123, in the peripheral active regions 105b at both sides of the peripheral gate pattern 118.

A preliminary impurity region 127 having a different conductivity type from the cell active region 105a in the semiconductor substrate 100 may be formed by implanting ions into the cell active region 105a. For example, when the cell active region 105a in the semiconductor substrate 100 is p type, the preliminary impurity region 127 may be n type. Meanwhile, not illustrated in the drawings, impurity ions for controlling threshold voltage and/or preventing or reducing leakage current may be implanted into the cell active region 105a.

An interlayer insulating layer 130 may be formed on the substrate having the peripheral transistor 125. The interlayer insulating layer 130 may be formed of a silicon oxide layer. An opening 130a exposing the cell active region 105a may be formed by performing a photolithography process on the interlayer insulating layer 130. The opening 130a in the interlayer insulating layer 130 may be formed to completely expose a top surface of the cell active region 105a in consideration of misalignment occurring during a semiconductor process. For example, a photoresist pattern may be formed on the interlayer insulating layer 130, an opening exposing the cell active region 105a may be formed by anisotropically etching the interlayer insulating layer 130 using the photoresist pattern as an etch mask, the opening may be expanded by isotropically etching the interlayer insulating layer 130 to completely expose the top surface of the cell active region 105a including the surface, which is not exposed by the misalignment, and then the photoresist pattern may be removed.

Meanwhile, the preliminary impurity region 127 may be formed by an ion implantation process after the opening 130a is formed in the interlayer insulating layer 130. Here, the preliminary impurity region 127 may be defined as a contact forming region.

In another example embodiment, the cell active region 105a exposed through the opening 130a in the interlayer insulating layer 130 may be isotropically etched. Thus, the cell active region 105a may have a top surface disposed at a lower level than the top surface of the peripheral active region 105b by the isotropic etching process. Further, the top surface of the cell active region 105a may be completely exposed by isotropically etching the cell active region 105a.

Referring to FIGS. 1 and 2C, a contact conductive layer 135 filling the opening 130a may be formed. The contact conductive layer 135 may be formed of a polysilicon layer. Forming the contact conductive layer 135 may include forming a conductive layer filling the opening 130a and covering the interlayer insulating layer 130, and planarizing the conductive layer to expose the top surface of the interlayer insulating layer 130.

Referring to FIGS. 1 and 2D, a mask pattern 140 having an opening 140a crossing the contact conductive layer 135 and extending onto the interlayer insulating layer 130 may be formed. A width of the opening 140a in the mask pattern 140 may be smaller than limiting resolution in the lithography process. For example, forming the mask pattern 140 may include forming first linear masks on the interlayer insulating layer 130, and forming second masks spaced apart from the first linear masks between the first masks. Forming the second masks may include forming sacrificial masks on sidewalls of the first linear masks, forming a second mask filling a vacant space between the sacrificial masks, and removing the sacrificial masks to form an opening.

The mask pattern 140 may be formed to include a material having an etch selectivity to the interlayer insulating layer 130, the contact conductive layer 135, and the cell active region 105a and isolation region 105s in the semiconductor substrate 100. For example, the mask pattern 140 may be formed of a silicon nitride layer. Meanwhile, the mask pattern 140 may be formed in a stack structure of a polysilicon layer and a silicon nitride layer, or a silicon oxide layer and a silicon nitride layer.

Referring to FIGS. 1 and 2E, the contact conductive layer 135 of FIG. 302D, the interlayer insulating layer 130, the cell active region 105a and the isolation region 105s may be etched using the mask pattern 140 as an etch mask. As a result, a gate trench region 145 crossing the cell active region 105a and extending to the isolation region 105s may be formed. That is, the gate trench region 145 may include an active trench region 145a crossing the cell active region 105a and a field trench region 145b extending to the isolation region 105s. The preliminary impurity region 127 of FIG. 2D may be divided by the gate trench region 145. That is, the preliminary impurity region 127 of FIG. 2D may be divided into a first impurity region 127a and a second impurity region 127b by the gate trench region 145.

In the cell active region 105a, a pair of the gate trench regions 145 may be formed. Thus, the preliminary impurity region 127 of FIG. 2D in the cell active region 105a may be divided into three regions, which includes cell source and drain regions 127a and 127b. For example, a pair of first impurity to regions spaced apart from each other in the cell active region 105a, i.e., a cell source region 127a, and a second impurity region spaced apart from the cell source regions 127a between the cell source regions 127a, i.e., a cell drain region 127b, may be formed.

Further, the contact conductive layer 135 of FIG. 2D may be etched, so as to form a first contact structure 135a and a second contact structure 135b, which are spaced apart from each other on the cell active region 105a. To be more specific, the first contact structure 135a may be formed on the first impurity region 127a in the cell active region 105a, and the second contact structure 135b may be formed on the second impurity region 127b in the cell active region 105a. The first contact structure 135a may be formed to have a sidewall in vertical alignment with a sidewall of the gate trench region 145 adjacent to the first impurity region 127a. That is, the first contact structure 135a may have a sidewall in vertical alignment with a sidewall of the first impurity region 127a facing the second impurity region 127b. The second contact structure 135b may have a sidewall in vertical alignment with a sidewall of the gate trench region 145 adjacent to the second impurity region 127b. That is, the second contact structure 135b may have a sidewall in vertical alignment with a sidewall of the second impurity region 127b facing the first impurity region 127a.

The first contact structure 135a may completely cover a top surface of the first impurity region 127a. Thus, a contact resistance characteristic between the first contact structure 135a and the first impurity region 127a may be improved. Further, the second contact structure 135b may completely cover a top surface of the second impurity region 127b. Thus, a contact resistance characteristic between the second contact structure 135b and the second impurity region 127b may be improved.

Referring to FIGS. 1 and 2F, a cell gate dielectric layer 150 may be formed on the gate trench region 145. The cell gate dielectric layer 150 may be formed by performing a thermal oxidation process or an atomic layer deposition process on the substrate having the gate trench region 145. The cell gate dielectric layer 150 may be formed of a thermal oxide layer or a high-k dielectric layer. The high-k dielectric layer may be a dielectric having a higher dielectric constant than the silicon oxide layer. A cell gate electrode 155 partially filling the gate trench region 145 may be formed on the cell gate dielectric layer 150. That is, a conductive material having a good gap-fill characteristic may be formed on the substrate having the cell gate dielectric layer 150, and etched back, so as to form the cell gate electrode 155 partially filling the gate trench region 145. The cell gate electrode 155 may comprise a metallic material or a polysilicon material. For example, the metallic material may comprise a metallic nitride such as a titanium nitride (TiN). Subsequently, an insulating pattern 160 filling the remaining portion of the cell trench region 145 may be formed. That is, an insulating material having a good fill characteristic may be formed on the substrate having the cell gate electrode 155 and planarized so as to form the insulating pattern 160 having a top surface disposed at substantially the same level as the top surfaces of the first and second contact structures 135a and 135b.

A method of fabricating a semiconductor device according to another example embodiment of the present invention will be described with reference to FIGS. 1, and 3A to 3E.

Referring to FIGS. 1 and 3A, a semiconductor substrate fabricated as according to the methods described above with reference to FIGS. 2 A and 2B is prepared. To be more specific, an isolation region 205s may be formed in the semiconductor substrate 200 having a first circuit region C and a second circuit region P to define active regions 205a and 205b. The isolation region 205s may be a trench isolation layer including a silicon oxide layer. The isolation region 205s may be formed in an inverted-trapezoidal shape in which an upper region has a larger width than a lower region, but embodiments of the present invention are not limited thereto. For example, the isolation region 205s may be formed in various shapes, such as a shape in which an upper region has substantially the same width as a lower region or a trapezoidal shape in which an upper region has a smaller width than a lower region.

A peripheral transistor 225 may be formed on the peripheral active region 205b in the semiconductor substrate 200. To be more specific, forming a peripheral gate pattern 218 may include forming a peripheral gate pattern 218 on the peripheral active region 205b, forming a gate spacer 220 on a sidewall of the gate pattern 218, and forming peripheral source and drain regions 223 in the peripheral active region 205b at both sides of the peripheral gate pattern 218. The peripheral gate pattern 218 may include a gate dielectric layer 210, a gate electrode 213 and a capping mask 216, which are sequentially stacked.

A lower interlayer insulating layer 230 may be formed on the substrate having the peripheral transistor 225. The lower interlayer insulating layer 230 may be formed of a silicon oxide layer. As in FIG. 2B, an opening 230a exposing the cell active region 205a may be formed by performing a photolithography process on the lower interlayer insulating layer 230.

Subsequently, the cell active region 205a exposed through the opening 230a in the lower interlayer insulating layer 230 may be isotropically etched and/or anisotropically etched. Thus, the cell active region 205a may have a top surface disposed at a lower level than a top surface of the peripheral active region 205b by the etching process. The cell active region 205a may have the top surface disposed at a lower level than the isolation region 205s.

Further, the top surface of the cell active region 205a may be completely exposed by an isotropic etching process. When the isolation region 205s is formed in an inverted-trapezoidal shape in which the upper region has a larger width than the lower region, the top surface of the cell active region 205a may be wider by the isotropic etching process. Further, even though the opening 230 in the interlayer insulating layer 230 is not perfectly self-aligned with the cell active region 205a due to misalignment, such that the interlayer insulating layer 230 partially overlaps the cell active region 205a, the top surface of the cell active region 205a may be completely exposed by the isotropic etching process.

As described in FIG. 2B, a preliminary impurity region 227 having a different conductivity type from the cell active region 205a in the semiconductor substrate 200 may be formed by implanting ions into the cell active region 205a. Here, the preliminary impurity region 127 may be defined as a contact forming region.

Subsequently, as illustrated in FIG. 3B, a contact conductive layer 235 filling the opening 230a may be formed. The contact conductive layer 235 may be formed of a polysilicon layer.

Referring to FIGS. 1 and 3C, the lower interlayer insulating layer 230 may be partially etched to expose a sidewall of an upper region of the contact conductive layer 235. Subsequently, a conductive spacer 236 may be formed on the sidewall of the upper region of the contact conductive layer 235. The conductive spacer 236 may be formed of a polysilicon layer.

Referring to FIGS. 1 and 3D, an upper interlayer insulating layer 238 may be formed by forming an insulating layer on the substrate having the conductive spacer 236 and planarizing the insulating layer to expose top surfaces of the contact conductive layer 235 and the conductive spacer 236. The upper interlayer insulating layer 238 may be formed of a silicon oxide layer.

By substantially the same method as descried in FIG. 2D, a mask pattern 240 having an opening 240a crossing the contact conductive layer 235 and extending onto the upper interlayer insulating layer 238 may be formed. The mask pattern 240 may be formed to include a material having an etch selectivity to the upper interlayer insulating layer 238, the lower interlayer insulating layer 230, the contact conductive layer 235, the conductive spacer 236, and the cell active region 205a and isolation region 205s in the semiconductor substrate 200. For example, the mask pattern 240 may be formed to include a silicon nitride layer.

Referring to FIGS. 1 and 3E, as described in FIG. 2E, the contact conductive layer 235 of FIG. 3D, the conductive spacer 236 of FIG. 3D, the upper interlayer insulating layer 238, the lower interlayer insulating layer 230, the cell active region 205a and the isolation region 205s may be etched using the mask pattern 240 as an etch mask. As a result, a gate trench region 245 including an active trench region 245a crossing the cell active region 205a and a field gate trench region 245b extending to the isolation region 205s from the active trench region 245a may be formed. The preliminary impurity region 227 of FIG. 3C may be divided into a first impurity region 227a and a second impurity region 227b, which are spaced apart from each other, by the gate trench region 245. In the cell active region 205a, a pair of the gate trench regions 245 spaced apart from each other may be formed. Thus, the preliminary impurity region 227 of FIG. 3C in the cell active region 205a may be divided into three regions, which includes first impurity regions spaced apart from each other, i.e., cell source regions 227a, and a second impurity region between the cell source regions 227a, i.e., a cell drain region 227b.

Further, the contact conductive layer 235 of FIG. 3D and the conductive spacer 236 of FIG. 3D may be etched to form a first contact structure 248a and a second contact structure 248b, which are spaced apart from each other, on the cell active region 205a. The first contact structure 248a may have a sidewall in vertical alignment with a sidewall of the gate trench region 245 adjacent to the first impurity region 227a. The second contact structure 248b may have a sidewall in vertical alignment with the sidewall of the gate trench region 245 adjacent to the second impurity region 227b. The first contact structure 248a may include a first contact pattern 235a electrically connected with the first impurity region 227a, and a first conductive contact spacer 236a provided on a sidewall other than a sidewall facing the second contact structure 248b among the sidewalls of an upper region of the first contact pattern 235a. The second contact structure 248b may include a second contact pattern 235b electrically connected with the second impurity region 227b and a second conductive contact spacer 236b provided on a sidewall other than the sidewall facing the first contact structure 248a among sidewalls of an upper region of the second contact pattern 235b. The first contact pattern 235a of the first contact structure 248a may completely cover a top surface of the first impurity region 227a. Thus, a contact resistance characteristic between the first contact structure 248a and the first impurity region 227a may be improved. Further, the second contact pattern 235b of the second contact structure 248b may completely cover a top surface of the second impurity region 227b. Thus, a contact resistance characteristic between the second contact structure 248b and the second impurity region 227b may be improved. The first and second contact structures 248a and 248b may be formed to have large top surface areas due to the first and second contact spacers 236a and 236b, respectively. Thus, when the present invention is applied to a memory device such as a DRAM, an interlayer insulating layer, a buried contact plug passing through the interlayer insulating layer and a DRAM capacitor on the buried contact plug may be formed in a following process. Here, because the first contact structure 248a according to some embodiments of the present invention has a larger top surface area due to the first contact spacer 236a, a contact area between the buried contact plug and the first contact structure increases, such that the contact resistance characteristic may be improved and a sufficient process margin to form the buried contact plug may be ensured.

Subsequently, as described in FIG. 2F, a cell gate dielectric layer 250 may be formed on the gate trench region 245, a cell gate electrode 255 partially filling the gate trench region 245 may be formed on the gate trench region 245, and an insulating pattern 260 filling the remaining portion of the gate trench region 245 may be formed on the cell gate electrode 255.

According to example embodiments of the present invention, a semiconductor device including a contact structure with an increased contact area is provided. Particularly, the contact structure of the present invention may completely cover top surfaces of source and drain regions. Thus, a contact resistance characteristic between the contact structure and the source and drain regions may be improved. Further, because the contact structure according to some embodiments of the present invention may be formed by forming a contact conductive layer in a large opening and etching the contact conductive layer using a linear mask pattern for forming a gate trench, a photolithography process for forming a fine contact hole with a relatively small size may be omitted. Furthermore, a contact structure is provided, which includes a contact pattern formed in the source and drain regions, and a conductive contact spacer formed on a sidewall of an upper region of the contact pattern. Because the contact structure has a relatively large top surface area due to the contact spacer, a contact area with another contact structure formed on the contact structure may increase and a sufficient process margin to form another contact structure may be ensured.

Example embodiments of the present invention have been disclosed herein and, although specific terms are used, they are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

That which is claimed:

1. A semiconductor device, comprising:
first and second regions formed in a semiconductor substrate and spaced apart from each other;
a first contact structure provided on the first region and having a sidewall in vertical alignment with a sidewall of the first region facing the second region; and
a second contact structure provided on the second region and having a sidewall in vertical alignment with a sidewall of the second region facing the first region.

2. The semiconductor device according to claim 1, wherein the first contact structure is electrically connected to the first region and covers a top surface of the first region, and the second contact structure is electrically connected to the second region and covers a top surface of the second region.

3. The semiconductor device according to claim 1, wherein the first contact structure comprises a first contact pattern electrically connected to the first region and a first conductive contact spacer provided on a sidewall other than a sidewall facing the second contact structure among sidewalls of an upper region of the first contact pattern, and the second contact structure comprises a second contact pattern electrically connected to the second region and a second conductive contact spacer provided on a sidewall other than a sidewall facing the first contact structure among sidewalls of an upper region of the second contact pattern.

4. A semiconductor device, comprising:
an isolation region formed in a semiconductor substrate to define an active region;
first and second impurity regions formed in the active region and spaced apart from each other;
a gate trench region crossing the active region between the first and second impurity regions and extending to the isolation region;
a first contact structure provided on the first impurity region and having a sidewall in vertical alignment with a sidewall of the gate trench region adjacent to the first impurity region;
a second contact structure provided on the second impurity region and having a sidewall in vertical alignment with a sidewall of the gate trench region adjacent to the second impurity region;
a gate electrode disposed on the gate trench region; and
a gate dielectric layer disposed between the gate trench region and the gate electrode.

5. The semiconductor device according to claim 4, wherein the first contact structure is electrically connected to the first impurity region and covers a top surface of the first impurity region, and the second contact structure is electrically connected to the second impurity region and covers a top surface of the second impurity region.

6. The semiconductor device according to claim 4, wherein the first contact structure comprises a first contact pattern electrically connected to the first impurity region and a first conductive contact spacer provided on a sidewall other than a sidewall facing the second contact structure among sidewalls of an upper region of the first contact pattern, and the second contact structure comprises a second contact pattern electrically connected to the second impurity region and a second conductive contact spacer provided on a sidewall other than a sidewall facing the first contact structure among sidewalls of an upper region of the second contact pattern.

7. The semiconductor device according to claim 4, wherein the gate electrode comprises a metallic material.

8. The semiconductor device according to claim 4, further comprising:
an other active region defined by the isolation region and spaced apart from the active region; and
a transistor provided on the other active region.

9. The semiconductor device according to claim 8, wherein the other active region has a top surface disposed at a higher level than a top surface of the active region.

10. A method of fabricating a semiconductor device, comprising:
providing a semiconductor substrate having a contact forming region formed therein;
forming an insulating layer having an opening on the semiconductor substrate so as to expose the contact forming region through the opening;
forming contact structures spaced apart from each other on the contact forming region exposed through the opening, wherein the contact structures are formed of a conductive material; and
etching the contact forming region between the contact structures so as to form a trench region for dividing the contact forming region.

11. The method according to claim 10, wherein forming the contact structures comprises:
forming a contact conductive layer filling the opening in the insulating layer; and
patterning the contact conductive layer.

12. The method according to claim 10, wherein the contact structures comprise contact patterns electrically connected to the contact forming region and conductive contact spacers formed on sidewalls other than sidewalls facing each other among sidewalls of upper regions of the contact patterns.

13. The method according to claim 12, wherein forming the contact structures comprises:
forming a contact conductive layer filling the opening in the insulating layer;
partially etching the insulating layer using the contact conductive layer as an etch mask to expose a sidewall of an upper region of the contact conductive layer;
forming a conductive spacer on the exposed sidewall of the upper region of the contact conductive layer; and
patterning the contact conductive layer and the conductive spacer to form the contact patterns and the conductive contact spacers.

14. A method of fabricating a semiconductor device, comprising:
forming an isolation region in a semiconductor substrate to define an active region;
forming an interlayer insulating layer having an opening on the semiconductor substrate having the isolation region to expose the active region through the opening;
forming a contact conductive layer filling the opening;
forming a mask pattern having an opening which crosses the contact conductive layer and extends onto the interlayer insulating layer;
etching the contact conductive layer, the interlayer insulating layer, the active region and the isolation region using the mask pattern as an etch mask to form a gate trench region that crosses the active region and extends to the isolation region and to form first and second contact structures spaced apart from each other on the active layer;
forming a gate dielectric layer on the gate trench region; and
forming a gate electrode on the gate dielectric layer to partially fill the gate trench region.

15. The method according to claim 14, further comprising:
forming a preliminary impurity region in the active region before forming the contact conductive layer, wherein the preliminary impurity region is divided by the gate trench region to define source and drain regions.

16. The method according to claim 14, further comprising:
etching the active region exposed through the opening using the interlayer insulating layer as an etch mask.

17. The method according to claim 14, further comprising:
forming a transistor on an other active region before forming the interlayer insulating layer, wherein the other active region is defined by the isolation region to be spaced apart from the active region in the semiconductor substrate.

18. A method of fabricating a semiconductor device, comprising:
forming an isolation region in a semiconductor substrate to define an active region;
forming an interlayer insulating layer having an opening on the semiconductor substrate having the isolation region to expose the active region through the opening;
forming a contact conductive layer filling the opening;
etching the interlayer insulating layer to expose a sidewall of an upper region of the contact conductive layer;
forming a conductive spacer on the exposed sidewall of the contact conductive layer;
forming a mask pattern having an opening that crosses the contact conductive layer and extends onto the interlayer insulating layer;
etching the contact conductive layer, the conductive spacer, the interlayer insulating layer, the active region and the isolation region using the mask pattern as an etch mask to form a gate trench region crossing the active region and extending to the isolation region;
forming a gate dielectric layer on the gate trench region; and
forming a gate electrode on the gate dielectric layer to partially fill the gate trench region.

19. The method according to claim 18, further comprising:
forming a preliminary impurity region in the active region before forming the contact conductive layer, wherein the preliminary impurity region is divided by the gate trench region to define source and drain regions.

20. The method according to claim 18, further comprising:
isotropically etching the active region exposed through the opening using the interlayer insulating layer as an etch mask.

21. The method according to claim 18, further comprising:
forming a transistor on an other active region before forming the interlayer insulating layer, wherein the other active region is defined by the isolation region to be spaced apart from the active region in the semiconductor substrate.
